(19) United States
(12) Patent Application Publication
(10) Pub. No.: US 2012/0193720 A1
(43) Pub. Date: Aug. 2, 2012

(54) SEMICONDUCTOR DEVICE

(76) Inventors: Seung-uk HAN, Suwon-si (KR); Young-jin Choi, Hwaseong-si (KR)

(21) Appl. No.: 13/348,786

(22) Filed: Jan. 12, 2012

(30) Foreign Application Priority Data
Feb. 1, 2011 (KR) 10-2011-0010307

(51) Int. Cl. H01L 27/088; H01L 29/78

(52) U.S. Cl. 257/368; 257/288; 257/E27.06; 257/E29.255

(57) ABSTRACT

The semiconductor device includes a substrate including an isolation region and an active region, the active region being defined by the isolation region; and a gate line including a first region on the active region, the first region including an open portion, and the open portion exposing a part of the active region, and a second region connected to the first region, the second region intersecting a boundary between the active region and the isolation region, a width of the second region being narrower than a width of the first region.

### CROSS-REFERENCE TO RELATED APPLICATIONS

Korean Patent Application No. 10-2011-0010307, filed on Feb. 1, 2011, in the Korean Intellectual Property Office, and entitled: “Semiconductor Device,” is incorporated by reference herein in its entirety.

### BACKGROUND

1. Field

The embodiments relate to semiconductor devices.

2. Description of the Related Art

With the development of the electronic industry and multi-media technology, integration densities and performance of semiconductor devices used in computers or mobile devices has improved. With an increase in the integration densities of semiconductor devices, design rules for elements of the semiconductor devices have been decreasing. In particular, in the case of a semiconductor device that requires a large number of transistors, a reduction in a transistor gate length which is a standard of the design rules, has resulted in a reduction in channel length.

### SUMMARY

One or more embodiments may provide a semiconductor device including a substrate having an isolation region and an active region, the active region being defined by the isolation region; and a gate line including a first region on the active region, the first region including an open portion, and the open portion exposing a part of the active region, and a second region connected to the first region, the second region intersecting a boundary between the active region and the isolation region, a width of the second region being narrower than a width of the first region. The width of the second region may be lowest at a portion of the second region corresponding to the boundary between the active region and the isolation region. The gate line may include at least one bent portion defined at an intersection between the first region and the second region. The open portion may exposes one of a source region and a drain region, the source region or the drain region being defined in the active region. Transistors formed by the gate line may share the exposed source or drain region exposed by the open portion. The source region and the drain region may be located in a P-type well. The isolation region may include a nitride liner.

The first region may be on the active region and spaced from the nitride liner by about 20 nanometers or more. The second region may extend from a portion centered between opposing horizontal sides of the first region.

The semiconductor device may further include a plurality of active regions and a plurality of gate lines, each of the plurality of active regions being divided into a plurality of regions by the plurality of gate lines, wherein the second region of each of the gate lines extends in a first direction, each of the plurality of active regions extend in a second direction perpendicular to the first direction, and the plurality of gate lines are parallel to each other in the second direction. Transistors formed by the gate lines may share a source region or a drain region between two adjacent gate lines. The plurality of active regions may be parallel to each other in the second direction, and a plurality of second regions may be connected between the plurality of active regions.

The semiconductor device may further include a sub-wordline driving circuit, wherein the gate line is a gate electrode of a p-type metal oxide semiconductor (PMOS) transistor of the sub-wordline driving circuit.

One or more embodiments may provide a semiconductor device including a substrate having an isolation region, and at least one active region, the active region being adjacent to the isolation region and extending in a direction; and at least one gate line located on the substrate, the gate line including an open portion, the open portion exposing a part of the at least one active region and extending in the direction, wherein the at least one gate line has a first width, the first width including a width of the open portion, and a second width, the second width being narrower than the first width at a position corresponding to the boundary between the at least one active region and the isolation region. The second width may be constant from a position corresponding to the boundary between the active region and the isolation region to a predetermined location.

One or more embodiments may provide a semiconductor device including a substrate having an isolation region and an active region, the active region being adjacent to the isolation region; and a gate line including a first region on the active region, the first region including an open portion, the open portion exposing a part of the active region, and a second region connected to the first region, the second region including a first portion on the active region and a second portion on the isolation region, wherein a width of the second region is narrower than a width of the first region.

The width of the second region may be less at the second portion than at the first portion. The second region may extend from opposing horizontal sides of the first region, the second region being perpendicular to the horizontal sides. The open portion may expose one of a source region and a drain region, the source region or the drain region being defined in the active region. Transistors formed by the gate line may share the exposed source or drain region exposed by the open portion.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic layout diagram of a semiconductor device according to an embodiment;

FIG. 2 illustrates a schematic layout diagram of a semiconductor device according to another embodiment;

FIG. 3 illustrates a perspective view of a semiconductor device according to an embodiment;

FIGS. 4A through 4G illustrate cross-sectional views of stages in a method of manufacturing a semiconductor device, according to an embodiment;

FIG. 5 illustrates a graph of off current characteristics of a semiconductor device according to an embodiment and of a comparative semiconductor device;

FIG. 6 illustrates a circuit diagram of a sub-wordline driving circuit including a semiconductor device according to an embodiment; and

FIG. 7 illustrates a block diagram of a semiconductor memory device in which the sub-wordline driving circuit of FIG. 6 is disposed, according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

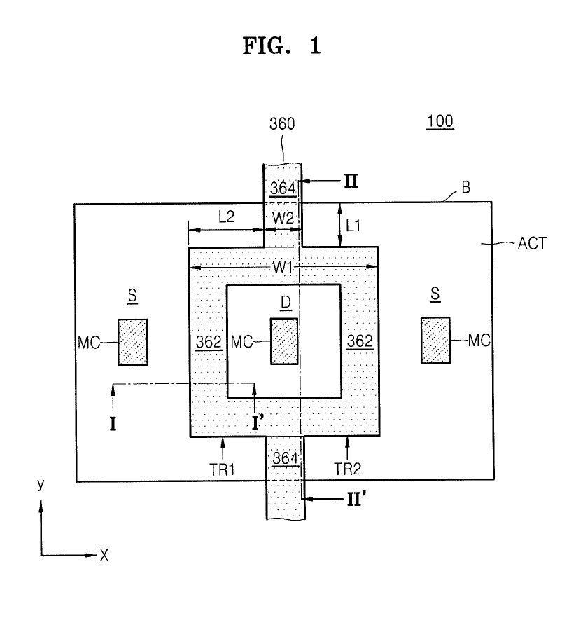

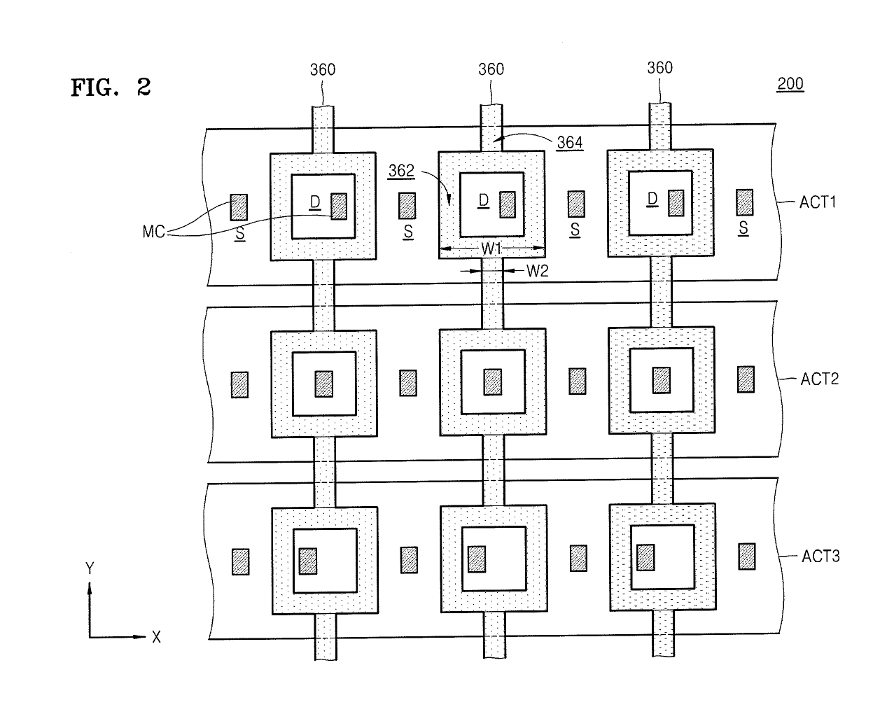

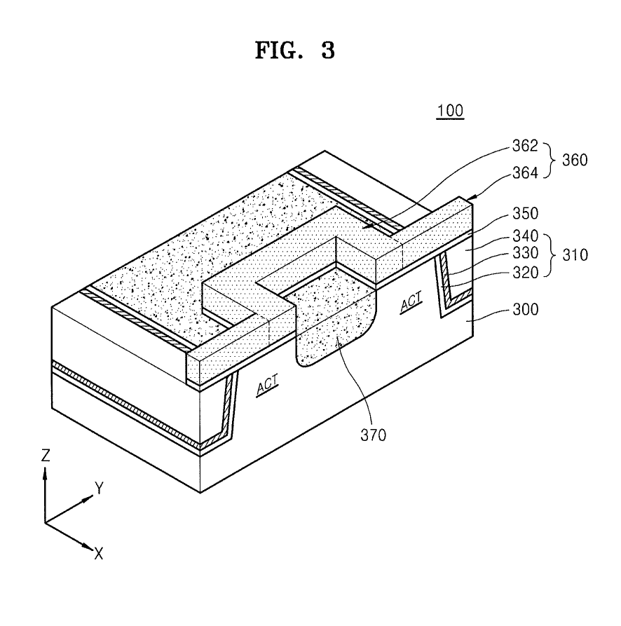

FIG. 1 illustrates a schematic layout diagram of a semiconductor device 100 according to an embodiment of the inventive concept. FIG. 2 illustrates a schematic layout diagram of the semiconductor device 200 according to another embodiment. FIG. 3 illustrates a perspective view of the semiconductor device 100 according to an embodiment. In more detail, FIG. 3 illustrates a cross-sectional perspective view taken along the line of FIG. 1.

Referring to FIGS. 1 and 3, the semiconductor device 100 may include an active region ACT formed in a substrate 300 and defined by an isolation region 310. The semiconductor device 100 may include a gate line 360 on the substrate 300 and contact plugs MC.

The active region ACT may be defined in the form of an island by the isolation region 310. The active region ACT may include three regions divided by the gate line 360. Each of the three regions includes at least one source region S and at least one drain region D. An impurity region 370 in FIG. 3 may correspond to one of the source region S and the drain region D. Although not illustrated, a well may be formed in the active region ACT including the source region S and the drain region D, by implanting an impurity, the conductive type of which is opposite to that of the substrate 300.

The contact plugs MC may be formed on the source region S and the drain region D. The contact plugs MC are not illustrated in FIG. 3. The contact plugs MC are arranged to apply voltages to the source region S and the drain region D for operation of the semiconductor device 100. The upper parts of the contact plugs MC may be connected to interconnection lines (not shown). Although not illustrated in FIG. 1 and FIG. 3, there may be a region in which the gate line 360 may also be connected to an interconnection line through an independent electric conductor having a plug form.

The substrate 300 may have a main surface extending in an X-axis direction and a Y-axis direction. The substrate 300 may include a semiconductor material such as a IV group semiconductor, a III-V group compound semiconductor, or a II-VI group oxide semiconductor. For example, the IV group semiconductor may include Si, Ge, or Si—Ge. The substrate 300 may be a bulk wafer or a wafer having an epitaxial layer.

The isolation region 310 may include a first insulation layer 320, a trench liner 330, and a second insulation layer 340, which are formed sequentially on a trench formed in the substrate 300. Each of the first insulation layer 320, the trench liner 330, and the second insulation layer 340 may include an oxide, a nitride, or a compound thereof For example, the first insulation layer 320 may include a buffer oxide. The trench liner 330 may include a nitride. The second insulation layer 340 may include high temperature oxide (HTO), high density plasma (HDP) material, tetra ethyl orthosilicate (TEOS), boron phosphorus silicate glass (BPSG), or undoped silicate glass (USG).

The gate line 360 may be formed on the substrate 300. The gate line 360 may intersect the active region ACT and extend in a direction, for example, the Y-axis direction. The gate line 360 may include a first region 362 and a second region 364. The first region 362 is formed on the active region ACT and divides the active region ACT into the source region S and the drain region D, e.g., the first region 362 may have a frame shape to define a drain region D inside the frame and a source region S outside the frame. The second region 364 may be connected to the first region 362 and may intersect the boundary between the active region ACT and the isolation region 310. The second region 364 may extend in the Y-axis direction. In the current specification, for convenience of explanation, the gate line 360 may be divided into the first region 362 and the second region 364, but the inventive concept is not limited thereto.

The first region 362 may include an open portion for exposing the drain region

D. The first region 362 may include a band, e.g., a tetragonal band that surrounds the open portion. For example, the first region 362 may have a tetragonal form or shape including a central open portion. In a modified embodiment, the first region 362 may have a round or an elliptical form or shape. Furthermore, the first region 362 may have a first width W1, which includes a width of the open portion. For example, the first width W1 may be defined by a distance in the X-axis direction between outermost edges of opposing sides, e.g., outermost sides extending along the Y-axis of the first region 362. If the first region 362 has a round or elliptical form according to an embodiment, the first width W1 may be a maximum width or a maximum diameter of the first region 362.

The first region 362 may be on the active region ACT. The first region 362 may be spaced from the boundary B between the active region ACT and the isolation region 310 by a first length L1. In other words, the first region 362 may be spaced apart by a predetermined distance from the trench liner 330, which is formed at an edge of the isolation region 310. The predetermined distance may be about 20 nm or more. In the case that the predetermined distance is relatively short, e.g., shorter than 20 nm, electrons generated in the drain region D by a voltage applied to the gate line 360 may be trapped in the trench liner 330.

The second region 364, e.g., a linear portion, may be connected to the first region 362 at opposing sides, e.g., sides extending along the x-axis of the first region 362. The second region 364 may extend in the Y-axis direction. A center of the second region 364 may coincide with a center of the first region 362 in the Y-axis direction. For example, the second region 364 may be spaced a second length L2, in the X-axis direction, from each vertical side of the first region 362, i.e., from each side of the first region 362 that extends along the Y-axis. According to some embodiments, the second region 364 may extend from a central portion of opposing horizontal sides of the first region 362, e.g., centered between opposing sides of the first region 362. The second region 364 may be perpendicular to the opposing horizontal sides of the first region 362. Thus, a bent portion may be formed at an intersection between the first region 362 and the second region 364.

The second region 364 may have a second width W2, e.g., along the X-axis, that is narrower than the first width W1 of the first region 362. In the embodiment illustrated in FIG. 1, the second region 364 is shown to have a constant second width W2, but the embodiments are not limited thereto. According to some embodiments, the width of the second region 364 may not be constant. For example, the second region 364 may have a minimum width at a position corresponding to the boundary between the active region ACT and the isolation region 310 that is less than a width of one or more other portions of the second region 364. According to some embodiments, the second width W2 may be the minimum width of the second region.

The gate line 360 may include a poly-silicon, a metal silicide, or a metal such as tungsten, e.g., the first region 362 and the second region 364 may include a same material. The gate line 360 may include a single layer or multiple layers. A gate insulation layer 350 may be interposed between the gate line 360 and the substrate 300. The gate insulation layer 350 may include, for example, a silicon oxide.

Transistors TR1 and TR2 may be disposed adjacent to each other, having the gate line 360 as their respective gate electrodes. The transistors TR1 and TR2 may be arranged so that the drain region D is shared by the transistors TR1 and TR2. The source region S and the drain region D may have a predetermined depth in the active region ACT. The source region S and the drain region D may correspond to an impurity region 370. The impurity region 370 may include an impurity such as boron (B), aluminum (Al), gallum (Ga), or zinc (Zn).

Typically, highly energized holes may be accelerated in a part of the active region ACT under a gate line of a semiconductor device, which is a channel region of the semiconductor device. The highly energized holes may generate hot electrons by impact ionization in a depletion region of a drain region. Thus, hot electrons are commonly trapped in a gate insulation layer adjacent to a drain region D, which reduces an effective channel length. Furthermore, the hot electrons may be trapped in a trench liner in an isolation region. Thus, a hot electron induced punch-through (HEIP) phenomenon may be generated. Due to this phenomenon, a leakage current may be generated at the interface of the active region. Thus, a leakage current in an off-state of the semiconductor device may be increased.

In the semiconductor device 100 according to example embodiments, a length of the gate line 360, i.e., a distance between opposing edges of the second region 364 in the X-axis direction, extending in one direction and intersecting with the trench liner 330 of the isolation region 310, may be minimized to the second width W2. Furthermore, the distance between the drain region D and the trench liner 330 may be increased. Accordingly, a phenomenon in which electrons are trapped in the trench liner 330 by the operation of the semiconductor device 100, may be minimized. Thus the HEIP phenomenon may be reduced. Furthermore, because the first region 362 has a bent portion in the active region ACT, an additional current path may be formed. Thus, an additional current may be secured.

Referring to FIG. 2 and FIG. 3, the semiconductor device 200 may include a plurality of active regions ACT1, ACT2, and ACT 3 extending in one direction, for example, in the X-axis direction. Each of the active regions ACT1, ACT2, and ACT 3 may include a plurality of regions divided by gate lines 360. Each of the plurality of regions may include a source region S or a drain region D. The isolation region 310 may be located between the adjacent active regions ACT1, ACT2, and ACT 3.

The plurality of gate lines 360 may be arranged parallel to each other and extend in the Y-axis direction perpendicular to the direction in which the active regions ACT1, ACT2, and ACT 3 extend. Each of the gate lines 360 may be arranged in the same manner as described above with respect to the embodiment of FIG. 1.

Contact plugs MC may be formed on the source region S and the drain region D. The contact plugs MC may be arranged to apply a voltage to the source region S and the drain region D for the operation of the semiconductor device 200. Upper parts of the contact plugs MC may be connected to interconnection lines (not shown). The contact plugs MC in the drain regions D may be formed on different axes or positions, e.g., offset, in the Y-axis direction, so that the interconnection lines to be formed on the upper parts of the contact plugs MC in the drain regions D do not contact each other. In a region not illustrated in FIG. 2 and FIG. 3, the gate lines 360 also may be connected to other interconnection lines through independent electric conductors having a plug form.

The second regions 364 may be arranged so that the first regions 362 of the adjacent active regions ACT1, ACT2, and ACT3 are connected to each other, e.g., through the second regions 364. In the connection parts or at the intersection between the first regions 362 and the second regions 364, each first region 362 may have a first width W1 in the X-axis direction. For example, each of the first regions 362 may have the first width W1, which is the maximum width, between edges of opposing vertical sides of the first region 362 in the X-axis direction. The second regions 364 may have a second width W2 which is narrower than the first width W1.

In the semiconductor device 200, a length of the gate lines 360, i.e., a distance between opposing edges of the second region 364 in the X-axis direction, extending in one direction and intersecting with the trench liner 330 of the isolation region 310, may be minimized to the second width W2. Furthermore, the distance between the drain region D and the trench liner 330 may be increased. Accordingly, the occurrence of a phenomenon in which electrons are trapped in the trench liner 330 by operation of the semiconductor device 200, may be minimized. Thus, the HEIP phenomenon may be reduced. Furthermore, an additional current path may be formed because the first regions 362 may have bent portions in the active regions ACT1, ACT2, and ACT3.

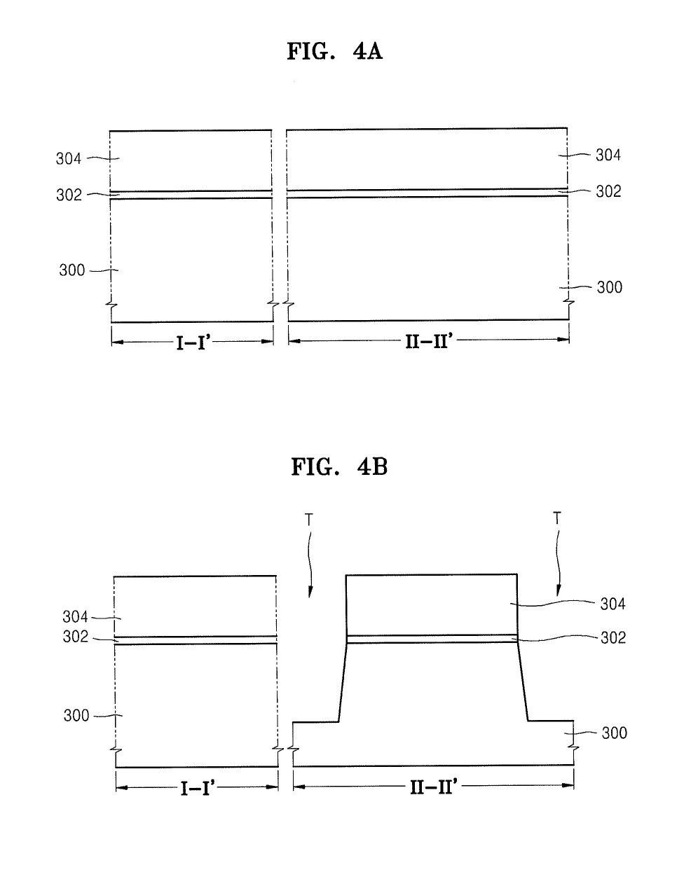

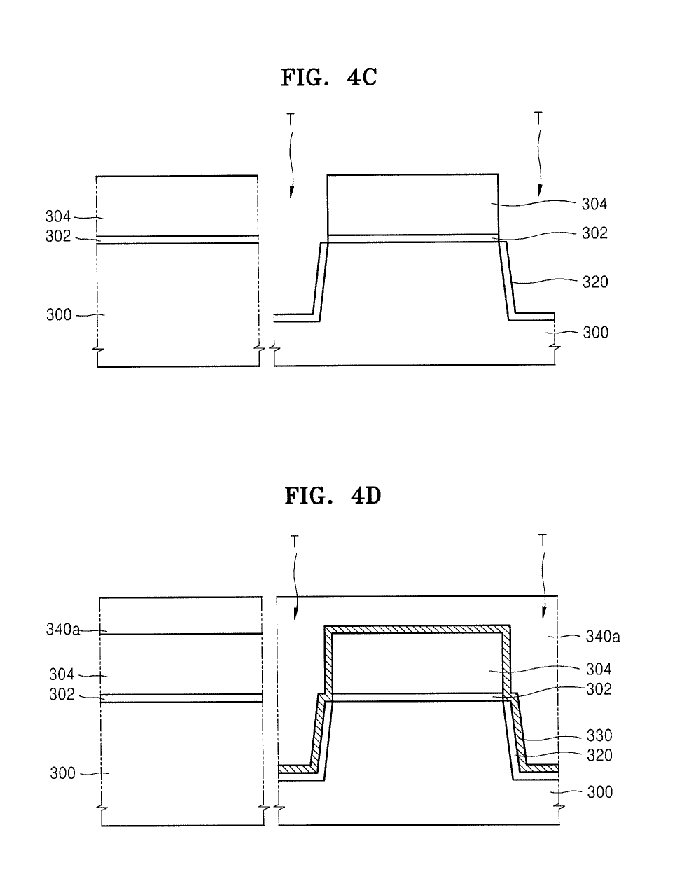

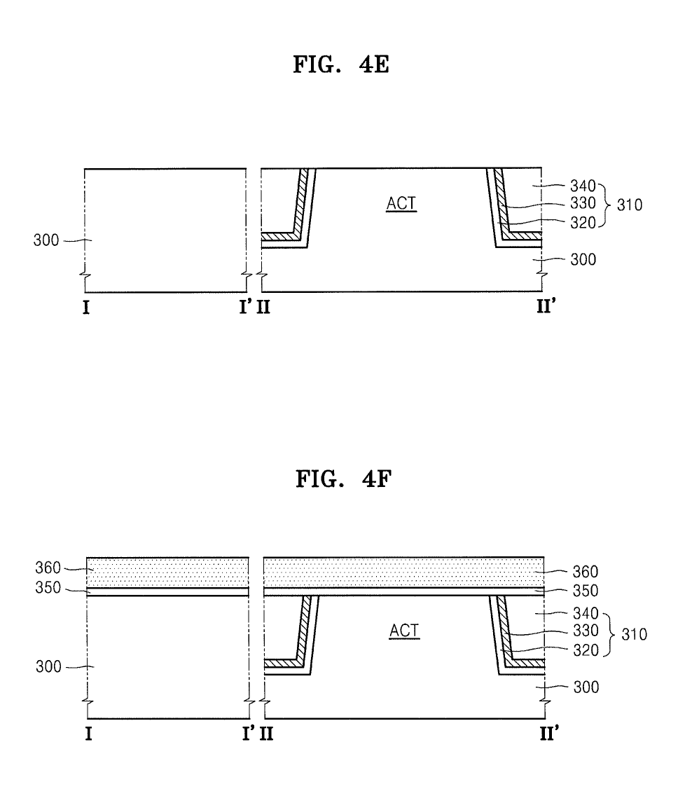

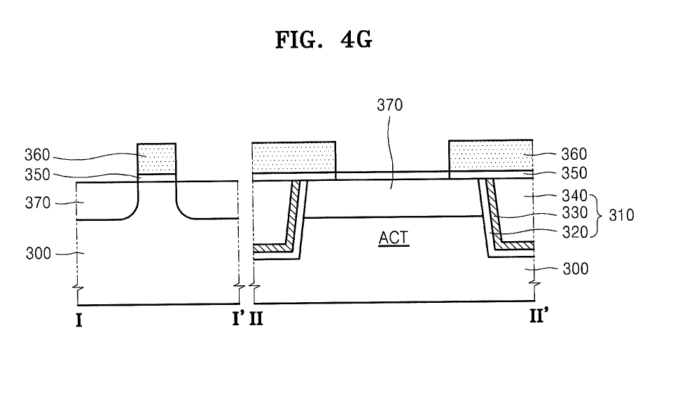

FIGS. 4A through 4G illustrate cross-sectional views of stages in a method of manufacturing a semiconductor device, according to an embodiment. FIG. 4A through FIG. 4G illustrate cross-sectional views of the schematic layout diagram of the semiconductor device in FIG. 1, taken along the lines I-I′ and

Referring to FIG. 4A, a pad layer 302 and a mask layer 304 may be formed on a substrate 300. The pad layer 302 may be, for example, a silicon oxide. The pad layer 302 may be formed by a thermal oxidation process or a chemical vapor deposition (CVD) process. The pad layer 302 may prevent a defect of the substrate 300 or stress in the substrate 300 when the mask layer 304 is deposited.

The mask layer 304 may include a material whose etch selectivity is different from those of the substrate 300 and the pad layer 302. The etch selectivity may be represented quantitatively by the ratio of an etching speed of the substrate 300 and the pad layer 302 to an etching speed of the mask layer 304. The mask layer 304 may be, for example, a hard mask including a silicon nitride. The mask layer 304 may include a plurality of layers including an organic layer.

The substrate 300 may include a semiconductor material such as a IV group semiconductor. The substrate 300 may include a well (not shown) formed by an ion implantation process.

Referring to FIG. 4B, an upper portion of the substrate 300 may include a trench T for device isolation. The upper portion of the substrate 300 may be exposed by patterning the pad layer 302 and the mask layer 304 with a pattern (not shown) such as a photoresist pattern.

The trench T for device isolation may be formed by etching the substrate 300 with patterns of the pad layer 302 and the mask layer 304. The trench T may be formed by an anisotropic etching process, for example, a plasma etching process. The depth of the trench T may be changed depending on desired characteristics of the semiconductor device 200. A side wall of the trench T may not be perpendicular to the upper portion of the substrate 300. For example, a width of the trench T may be less at a lower portion of the substrate 300 than at a higher portion of the substrate 300. After the trench T is formed, an ion implantation process may be additionally performed to strengthen insulation characteristics.

Referring to FIG. 4C, a first insulation layer 320 may be formed in the trench T. The first insulation layer 320 may include a thermal oxide layer which is formed by a radical oxidation method using a furnace or a rapid thermal annealing (RTA) method. The insulation layer 320 may be formed by depositing an insulation material. In this case, the insulation material may also be deposited on the mask layer 304. The insulation layer 320 may be formed, for example, to a depth of 200A or less.

Referring to FIG. 4D, a trench liner 330 may be formed on the insulation layer 320. The trench liner 330 may include, for example, a nitride and may be formed by using low pressure chemical vapor deposition (LPCVD). The trench liner 330 may be formed, for example, to a depth of 50 Å through 200 Å. In the case of a DRAM (Dynamic Random Access Memory) device, a trench liner including a nitride layer may be used to improve refresh characteristics. One or more embodiments may avoid or minimize HEIP phenomenon associated with electrons becoming trapped in a trench liner when a nitride layer is included in the trench liner.

Next, a second insulation layer 340a may be formed on the trench liner 330. The second insulation layer 340a may be formed by the CVD process. The second insulation layer 340a may include an oxide. For example, the second insulation layer 340a may include a HTO, a HDP, a TEOS, a BPSG, or a USG. After the second insulation layer 340a is formed, an annealing process may be performed to increase a density of the second insulation layer 340a.

Referring to FIG. 4E, after the second insulation layer 340a is formed so that the trench T is filled, a planarization process may be performed. For example, the planarization process may be a chemical mechanical polishing (CMP) process. The mask layer 304, the pad layer 302, and the upper portion of the second insulation layer 340a may be removed by the planarization process.

After the planarization process is performed, a buried isolation region 310 is obtained. The isolation region 310 may include the first insulation layer 320, the trench liner 330, and the second insulation layer 340. An active region ACT may be defined in the substrate 300 by the isolation region 310.

Referring to FIG. 4F, a gate insulation layer 350 and a gate line 360 may be formed on the substrate 300. The gate insulation layer 350 may include a silicon oxide (SiO₂), a high-k dielectric material, or a compound layer having a silicon oxide (SiO₂) and a silicon nitride (SiN). Here, the high-k dielectric material means a dielectric material having a higher dielectric constant than that of an oxide layer.

The gate line 360 may include a polysilicon or a metal such as tungsten (W). Furthermore, a metal silicide layer may be included in the upper portion of the gate line 360. The gate line 360 may function as a gate electrode of a transistor and may extend in a direction to facilitate connection with an interconnection line (not shown).

Referring to FIG. 4G, a patterning process may be performed to pattern the gate insulation layer 350 and the gate line 360. For clarification, FIG. 4G illustrates only a cross sectional view taken along the lines I-I′ and II-IF shown in FIG. 1. After forming a mask layer (not shown), for example, a photoresist layer, and patterning it, an exposed portion of the gate line 360 and a portion of the gate insulation layer 350 under the exposed gate line 360 may be removed by an etching process.

Next, an impurity region 370 may be formed by implanting an impurity while using the gate line 360 as a mask. The impurity region 370 may function as a source region (S) (refer to FIG. 1) and a drain region (D) (refer to FIG. 1) of the transistor in which the gate line 360 functions as a gate electrode. Although not illustrated, after forming a spacer including an insulation material at a side wall of the gate line 360, the impurity implantation process may be performed.

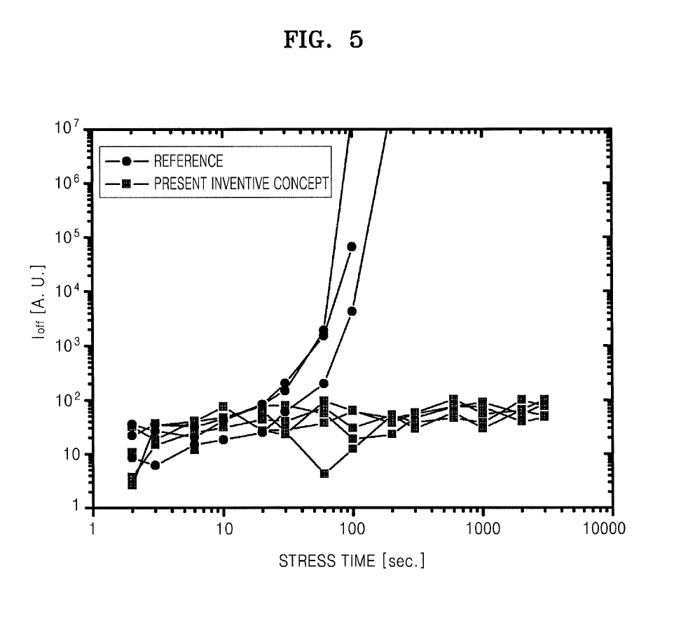

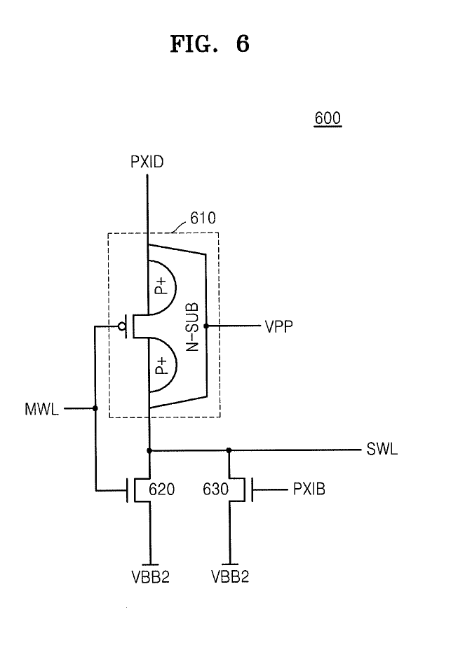

FIG. 5 illustrates a graph of off current characteristics of a semiconductor device according to an embodiment.

Referring to FIG. 5, an off current I_{off} may be measured according to a stress time by applying a constant voltage to a gate line of the semiconductor device. The off current I_{off} may be represented by an arbitrary unit. The term “REFERENCE” in FIG. 5 refers to a reference transistor in which the inventive concept is not applied.

The reference transistor may have a form in which the second width W2 is equal to the first width W1, i.e., a gate line with a uniform width without bent portions, so a length of the drain region D in the Y-axis direction is longer than that of the semiconductor device 100, according to example embodiments.

In the reference transistor, the off current I_{off} may increase significantly at a stress time of about 100 seconds or less. However, in the semiconductor device according to an embodiment, the off current I_{off} may hardly vary even up to a stress time of about 1000 seconds or more.

As described above, a leakage current may not be generated in the off state of the transistor (the semiconductor device) according to an embodiment of the inventive concept. Thus, the HEIP phenomenon may be reduced. It is believed that the transistor, according to an embodiment of the inventive concept, may have a reduced occurrence of HEIP because a length of the gate line 360 extending in one direction and intersecting the trench liner 330 of the isolation region 310 may be minimized and the distance between the drain region D and the trench liner 330 may increase. As a result, a phenomenon in which electrons are trapped in the trench liner 330 may be minimized.

FIG. 6 illustrates a circuit diagram of a sub-wordline driving circuit including a semiconductor device according to an embodiment.

Referring to FIG. 6, the sub-wordline driving circuit 600 may be a circuit for driving a sub-wordline in a semiconductor memory device and may include a p-type metal oxide semiconductor (PMOS) transistor 610, a first n-type metal oxide semiconductor (NMOS) transistor 620, and a second NMOS transistor 630.

The PMOS transistor 610 may have a source connected to a select signal receiving terminal PXID and a drain connected to a sub-wordline SWL, and may be controlled by a main-wordline driving signal MWL. The first NMOS transistor 620 may be connected between the sub-wordline SWL and a ground voltage terminal VBB2 and may be controlled by the main-wordline driving signal MWL. The second NMOS transistor 630 may be connected between the sub-wordline SWL and the ground voltage terminal VBB2 and may be controlled by an inverted sub-wordline select signal PXIB.

The sub-wordline driving circuit 600 may drive the sub-wordline SWL in response to the main-wordline driving signal MWL. First, when both the main-wordline driving signal MWL and the inverted sub-wordline select signal PXIB are set to the logic low level, the PMOS transistor 610 may be turned on. Thus, the sub-wordline SWL may be driven to a boosted voltage VPP. Although not illustrated in FIG. 6, a plurality of memory cells may be connected to the sub-wordline SWL and may be activated according to a driving voltage level of the sub-wordline SWL.

Next, when both the main-wordline driving signal MWL and the inverted sub-wordline select signal PXIB are set to the logic high level, the first NMOS transistor 620 may be turned on. Thus, the sub-wordline SWL may be driven to a ground voltage VBB2. The PMOS transistor 610 may receive the boosted voltage VPP as a substrate bias voltage and may be controlled by the main-wordline driving signal MWL. Thus, the PMOS transistor 610 may be turned off when the main-wordline driving signal MWL is set to the logic high level, i.e., the boosted voltage VPP.

The PMOS transistor 610 may have a structure in accordance with one or more embodiments. Accordingly, any potential deterioration in the reliability of the transistor associated with the HEIP phenomenon may be prevented even at the high level boosted voltage VPP.

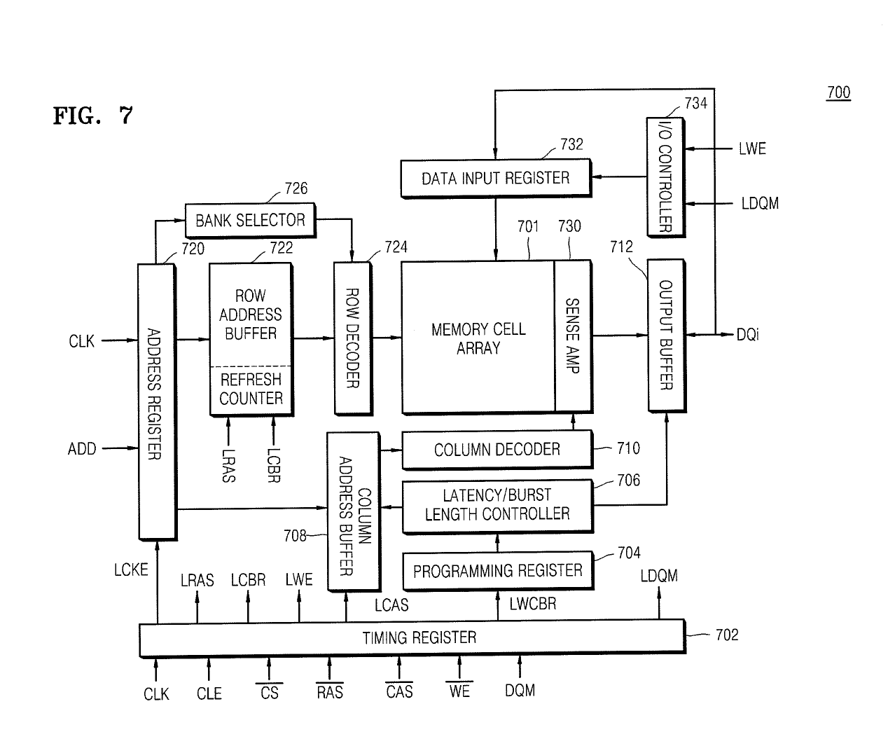

FIG. 7 illustrates a block diagram of a semiconductor memory device in which the sub-wordline driving circuit of FIG. 6 is arranged.

Referring to FIG. 7, the semiconductor memory device 700 may include a memory cell array 701 having a plurality of DRAM cells and various circuit blocks for driving the DRAM cells. For example, a timing register 702 may be activated when a chip select signal/CS is changed from a non-active level (for example, logic high) to an active level (for example, logic low). The timing register 702 may receive command signals, such as, a clock signal CLK, a clock enable signal CKE, a chip select signal/CS, a row address strobe signal/RAS, a column address strobe signal/CASB, a write enable signal/WE, and a data input/output (I/O) mask signal DQM. The timing register 702 may process the command signals and generate various internal command signals, such as, LASB, LCBR, LWE, LCAS, LWCBR, and LDQM for controlling circuit blocks.

A programming register 704 may store some of the internal command signals, such as, LASB, LCBR, LWE, LCAS, LWCBR, and LDQM. For example, latency information or burst length information, which is related to a data output, may be stored in the programming register 704. The internal command signals stored in the programming register 704 may be provided to a latency/burst length controller 706. The latency/burst length controller 706 may provide a control signal for controlling the latency or the burst length of output data to a column decoder 710 through a column address buffer 708 and provide the control signal to an output buffer 712.

An address register 720 may receive address signals ADD from the outside. A row address signal output from the address register 720 may be provided to a row decoder 724 through a row address buffer 722. A column address signal output from the address register 720 may be provided to a column decoder 710 through a column address buffer 708. The row address buffer 722 may further receive a refresh address signal, which is generated in a refresh counter in response to refresh command signals LRAS and LCBR. The row address buffer may provide one of the row address signals and the refresh address signal to the row decoder 724. Furthermore, the address register 720 may provide a bank signal for selecting a bank to a bank selector 726.

The row decoder 724 may decode the row address signal or the refresh address signal and activate a wordline of the memory cell array 701. The sub-wordline driving circuit of FIG. 6, which may be a sub-wordline driving circuit, including a semiconductor device according to an embodiment, may be arranged in the form of blocks at predetermined intervals in the memory cell array 701. Furthermore, the sub-wordline driving circuit may be arranged between the memory cell array 701 and the row decoder 724.

The column decoder 710 may decode the column address signal and perform an operation for selecting a bitline of the memory cell array 701. For example, the column decoder 710 may perform an operation for selecting a bitline through a column select line of the memory cell array 700.

A sense amplifier 730 may amplify data of a memory cell selected by the row decoder 730 and the column decoder 710 and provide the amplified data to the output buffer 712. Write data may be provided to the memory cell array 701 through a data input register 732. An input/output (I/O) controller 734 may control an operation of transferring data through the data input register 732.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device comprising:
a substrate including an isolation region and an active region, the active region being defined by the isolation region; and
a gate line including
a first region on the active region, the first region including an open portion, and the open portion exposing a part of the active region, and
a second region connected to the first region, the second region intersecting a boundary between the active region and the isolation region, a width of the second region being narrower than a width of the first region.

2. The semiconductor device of claim 1, wherein the width of the second region is lowest at a portion of the second region corresponding to the boundary between the active region and the isolation region.

3. The semiconductor device of claim 1, wherein the gate line includes at least one bent portion defined at an intersection between the first region and the second region.

4. The semiconductor device of claim 1, wherein the open portion exposes one of a source region and a drain region, the source region or the drain region being defined in the active region.

5. The semiconductor device of claim 4, wherein transistors formed by the gate line share the exposed source or drain region exposed by the open portion.

6. The semiconductor device of claim 4, wherein the source region and the drain region are located in a P-type well.

7. The semiconductor device of claim 1, wherein the isolation region includes a nitride liner.

8. The semiconductor device of claim 7, wherein the first region is on the active region and spaced from the nitride liner by about 20 nanometers or more.

9. The semiconductor device of claim 1, wherein the second region extends from a portion centered between opposing horizontal sides of the first region.

10. The semiconductor device of claim 1, further including a plurality of active regions and a plurality of gate lines, each of the plurality of active regions being divided into a plurality of regions by the plurality of gate lines, wherein the second region of each of the gate lines extends in a first direction, each of the plurality of active regions extend in a second direction perpendicular to the first direction, and the plurality of gate lines are parallel to each other in the second direction.

11. The semiconductor device of claim 10, wherein transistors formed by the gate lines share a source region or a drain region between two adjacent gate lines.

12. The semiconductor device of claim 10, wherein the plurality of active regions are parallel to each other in the second direction, and a plurality of second regions are connected between the plurality of active regions.

13. The semiconductor device of claim 1, further comprising a sub-wordline driving circuit,
wherein the gate line is a gate electrode of a p-type metal oxide semiconductor (PMOS) transistor of the sub-wordline driving circuit.

14. A semiconductor device comprising:
a substrate including an isolation region, and at least one active region, the active region being adjacent to the isolation region and extending in a first direction; and
at least one gate line located on the substrate, the gate line including an open portion, the open portion exposing a part of the at least one active region and extending in the first direction,
wherein the at least one gate line has a first width, the first width including a width of the open portion, and a second width, the second width being narrower than the first width at a position corresponding to a boundary between the at least one active region and the isolation region.

15. The semiconductor device of claim 14, wherein the second width is constant from a position corresponding to the boundary between the active region and the isolation region to a predetermined location.

16. A semiconductor device comprising:
a substrate including an isolation region and an active region, the active region being adjacent to the isolation region; and
a gate line including
a first region on the active region, the first region having a frame shape exposing a part of the active region in a center of the first region, and
a second region extending from an edge of the first region, the second region including a first portion on the active region and a second portion on the isolation region,
wherein a width of the second region is narrower than a width of the first region.

17. The semiconductor device of claim 16, wherein the width of the second region is less at the second portion than at the first portion.

18. The semiconductor device of claim 16, wherein the second region extends from opposing horizontal sides of the first region, the second region being perpendicular to the horizontal sides.

19. The semiconductor device of claim 16, wherein the open portion exposes one of a source region and a drain region, the source region or the drain region being defined in the active region.

20. The semiconductor device of claim 16, wherein transistors formed by the gate line share the exposed source or drain region exposed by the open portion.
